(19) United States
(12) Patent Application Publication
(10) Pub. No.: US 2009/0168508 A1
(43) Pub. Date: Jul. 2, 2009

(54) Static random access memory having cells with junction field effect and bipolar junction transistors

(75) Inventors: Ashok K. Kapoor, Palo Alto, CA (US); Damodar R. Thummalapally, Milpitas, CA (US); Abhijit Ray, Sunnyvale, CA (US)

Correspondence Address: HAVERSTOCK & OWENS, LLP, 162 North Wolfe, Sunnyvale, CA, 94086, US

(73) Assignee: DSM Solutions, Inc.

(21) Appl. No.: 12/006,349

(22) Filed: Dec. 31, 2007

(51) Int. Cl. G11C 11/34

(52) U.S. Cl. 365/177

(57) ABSTRACT

A static random access memory (SRAM) device can include at least one SRAM cell having storage section that includes at least a first junction field effect transistor (JFET) with a gate terminal formed from a semiconductor layer deposited on a substrate surface. The storage section can also include at least a first storage node that provides a potential corresponding to a stored data value. The SRAM cell further includes a first access section that includes at least a first bipolar junction transistor (BJT) having an emitter formed from the semiconductor layer.

### TECHNICAL FIELD

The present invention relates generally to memory devices, and more particularly to static random access memory (SRAM) devices that include junction field effect transistors (JFETs).

### BACKGROUND OF THE INVENTION

Static random access memories (SRAMs) are typically used to provide rapid access to stored data. Unlike dynamic RAMs, which store data on a capacitor that can leak and thus require time for refreshing, SRAMs can utilize a latching circuit that can continuously provide a strong read data signal for access at essentially any time. Such a strong read signal and no need for refresh enables SRAMs to have very fast access speeds.

Conventional SRAMs typically include a pair of cross-coupled metal-oxide-semiconductor field effect transistors (MOSFETs) as a latching circuit that provides complementary data values at their drains. An access device can be used to provide a read data path from, or write data path to, the stored data value. SRAM cells having but one access device are called “single ended”. In most cases, a conventional SRAM cell includes two access devices to create a differential data signal that can provide for more reliable read operations.

In addition to a cross-coupled latching pair, conventional SRAM cells can include a load circuit (i.e., resistors) or a pair of opposite conductivity type MOSFETs arranged in a cross coupled fashion between the drains of the first MOSFET pair. Conventional SRAM cells having the latter configuration have been referred to as four-transistor (4T) cells, while conventional SRAM cells having the former configuration have been referred to as a six-transistor (6T) cells.

While conventional SRAMs have historically provided rapid access speeds for data storage applications, as MOSFETs have scaled to smaller and smaller channel sizes, conventional SRAMs have become less desirable for many applications. At smaller channel sizes, MOSFETs can suffer from considerable sub-threshold channel leakage, resulting in undesirably large power consumption. Further, in the case of 6T type cells, sufficient power supply voltages are needed (i.e., headroom) to ensure that transistors of both conductivity types (n-channel and p-channel) are sufficiently turned off when latching data.

### BRIEF SUMMARY OF THE INVENTION

A static random access memory (SRAM) device can include at least one SRAM cell having a storage section that includes at least a first junction field effect transistor (JFET) having a gate terminal formed from a semiconductor layer deposited on a substrate surface and at least one storage node that provides a potential corresponding to a stored data value. In addition, a first access section can include at least a first bipolar junction transistor (BJT) having an emitter formed from the same semiconductor layer as the SRAM gate terminal.

### BRIEF DESCRIPTION OF THE DRAWINGS

FIG. 1 shows a static random access memory (SRAM) cell according to a first embodiment.

FIG. 2 shows an SRAM cell according to a second embodiment.

FIG. 3 shows an SRAM cell according to a third embodiment.

FIG. 4 shows an SRAM cell according to a fourth embodiment.

FIGS. 5A to 5D show various bipolar junction transistor (BJT) connection arrangements for SRAM cells according to the embodiments.

FIGS. 6A and 6B show SRAM cells according to two more embodiments.

FIGS. 7A and 7B show SRAM cells according to two more embodiments.

FIGS. 8A to 8C show SRAM cells according to three more embodiments.

FIGS. 9A to 9C are timing diagrams showing operations for the embodiments shown in FIGS. 8A to 8C.

FIGS. 10A and 10B show SRAM cells according to two more embodiments.

FIGS. 11A and 11B show SRAM cells according to two more embodiments.

FIGS. 12A and 12B show SRAM cells according to two more embodiments.

FIG. 13 is a top plan view showing an SRAM device layout according to an embodiment.

FIG. 14 is a top plan view showing an SRAM device layout according to another embodiment.

FIG. 15 is a top plan view showing an SRAM device layout according to yet another embodiment.

FIG. 16 is a top plan view showing one example of manufacturing layers for an SRAM device layout like that of FIG. 15.

FIG. 17 is a side cross sectional view showing devices that can be included in the embodiments.

FIG. 18A is a side cross sectional view showing other devices that can be included in the embodiments. FIG. 18B is a side cross sectional view showing still other devices that can be included in the embodiments.

FIG. 19 is a side cross sectional view showing an alternate way of forming a BJT that can be included in the embodiments.

FIGS. 20A and 20B show current sense amplifiers that can be included in the embodiments.

FIG. 21 is a blocks schematic diagram of an SRAM device according to an embodiment.

### DETAILED DESCRIPTION OF THE EMBODIMENTS

Various embodiments of the present invention will now be described in detail with reference to a number of drawings. The embodiments show devices and methods related to static random access memory (SRAM) cells, including integrated circuit devices including such cells, where such cells include junction field effect transistors (JFETs) for storing a data value, and one or more bipolar junction field effect transistors (BJTs) for accessing such a stored data value.

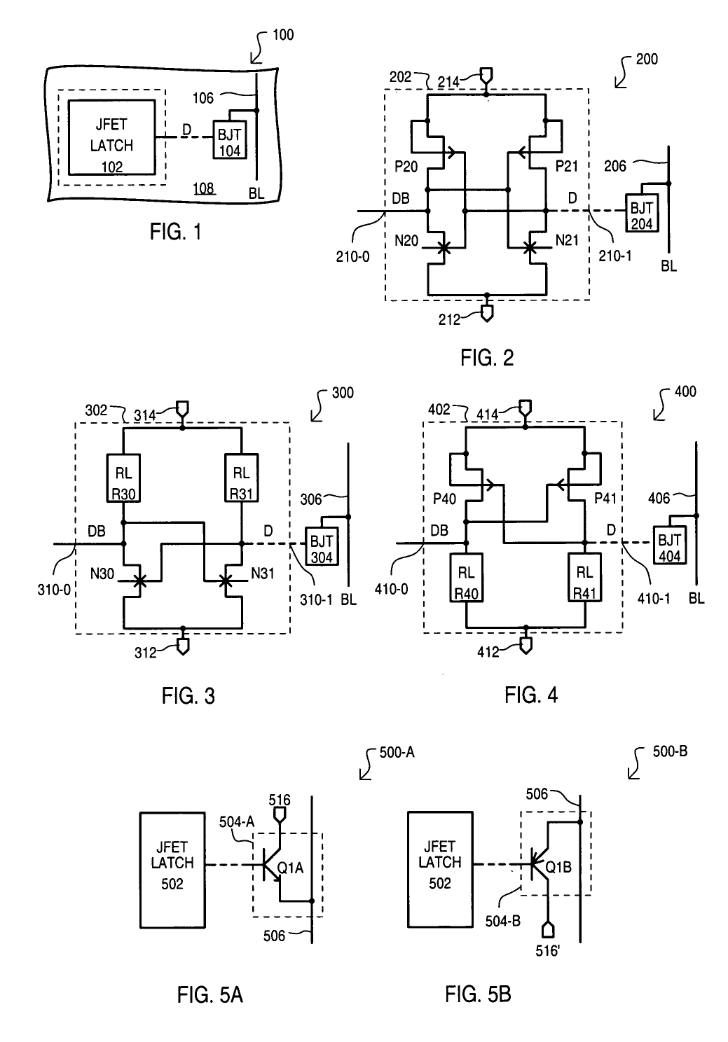

In the various embodiments shown, like items are referred by the same reference character but with the first digit corresponding to the figure number (e.g., memory cells are labeled “102” in FIG. 1, 202 in FIG. 2, etc.).

Referring now to FIG. 1, an SRAM cell according to a first embodiment is shown in block schematic diagram and designated by the general reference character 100. An SRAM cell 100 can include a latch circuit 102, an access circuit 104, and a bit line 106. A latch circuit 102 can include JFET devices that can store a data value D. Preferably, a latch circuit 102 can have active circuit components composed only of JFET devices. Even more particularly, JFETs of a latch circuit 102 can be enhancement mode JFETs having terminals (e.g., gate, source, or drain) formed by patterning a doped semiconductor layer formed on a surface of substrate. Such enhancement mode JFETs can have advantageously low leakage currents as compared to metal-oxide-semiconductor field effect transistors (MOSFETs) of comparable size.

An access circuit 104 can allow a data value D to be translated to bit line 106 in a data read operation. An access circuit 104 can include one or more BJTs, and is preferably composed only of BJTs. In particular, an access circuit 104 can include a single BJT having one terminal connected to latch circuit 102 and another terminal connected to bit line 106. Preferably, a BJT of an access circuit 104 can include terminals (e.g., emitter, collector, or base) formed by patterning the same layer used to form terminals for JFETs of latch circuit 102.

Referring still to FIG. 1, in a preferred embodiment, a latch circuit 102 and access circuit 104 can be formed in a same substrate 108 to form an integrated circuit device.

Utilizing enhancement mode JFET device for latch circuit 102 can result in advantageously low leakage currents for an SRAM cell as compared to MOSFET based cells, particularly at small channel sizes. Utilizing a BJT to access a stored value can result in rapid read times for an SRAM cell 100.

In this way, an SRAM cell can include a latch circuit formed with JFET devices and an access circuit formed with one or more BJT devices.

Referring now to FIG. 2, an SRAM cell according to another embodiment is shown in block schematic diagram and designated by the general reference character 200. In a very particular arrangement, the embodiment of FIG. 2 can be one example of the embodiment shown in FIG. 1. SRAM cell 200 can include a latch circuit 202 and access circuit 204. Latch circuit 202 can include two pairs of JFETs arranged in a cross coupled fashion between a first data node 210-0 and a second data node 210-1. More particularly, latch circuit 202 includes a first pair of n-channel JFETs (NJFETs) N20/N21 and a second pair of p-channel JFETs (PJFETs) P20/P21. Transistor N20 can have a source connected to a first latch power supply node 212, a drain connected to first data node 210-0 and a gate connected to second data node 210-1. Transistor N21 can have a source connected to a first latch power supply node 212, a drain connected to second data node 210-1 and a gate connected to first data node 210-0. Transistors P20 and P21 can have drains and gates connected between first and second data nodes (210-0 and 210-1) in the same cross-coupled fashion as transistors N20 and N21, and can have their sources commonly connected to a second latch supply node 214. In such an arrangement, latch circuit 202 can store a data value D, in complementary form at data nodes 210-0 and 210-1. In the particular arrangement of FIG. 1, second data node 210-1 can store data value “D”, while first data node can store its complement “DB”. That is, in a latching state, value D will have one potential (VHI or VLO), while value DB will have the opposite latched value (VLO or VHI).

It is noted that latch supply nodes (212 and/or 214) can be static or dynamic voltages. For example, in one arrangement, both latch supply nodes (212 and 214) can be constant across various types of operation, such as store, read and/or write operations. However, in alternate arrangements, a potential applied to such supply nodes can vary according to operation. In particular, and as will be described in more detail below, either one or both latch supply nodes (212 and/or 214) can receive one potential when storing data or during write operation, and receive another potential during read operations.

An access circuit 204 can include one or more BJTs having a terminal connected to second data node 210-1. Thus, according to a stored data value (e.g., D=VHI or VLO), the conductivity of access circuit 204 can be altered. As a result, a current drawn on bit line 206 can reflect a data value stored by latch circuit 204. In the arrangement of FIG. 2, a connection between access circuit 204 and second data node 210-1 is shown with a dashed line to indicate that such a connection can be direct (e.g., such a connection includes an uninterruptible low impedance path) or indirect (e.g., such a connection includes a controllable impedance path). More detailed examples of such connections will be described in other embodiments below.

In this way, an SRAM cell can include a latch circuit having JFET devices cross-coupled between complementary data storage nodes, as well as a BJT access circuit connected one or more of the data storage nodes.

Referring now to FIG. 3, an SRAM cell according to another embodiment is shown in block schematic diagram and designated by the general reference character 300. In a very particular arrangement, the embodiment of FIG. 3 can be one example of the embodiment shown in FIG. 1. An SRAM cell 300 has the same general structure as that shown in FIG. 2, but instead of PJFETs P20/P21, it includes pull-up load resistors R30 and R31. Otherwise, an SRAM cell 300 can operate in the same general fashion as the SRAM cell of FIG. 2, and be subject to the same variations in construction.

Similarly, FIG. 4 shows an SRAM cell according to another embodiment like that of FIG. 2. In a very particular arrangement, the embodiment of FIG. 3 can be one example of the embodiment shown in FIG. 1. FIG. 4 can differ from FIG. 2 in that instead of NJFETs N20/N21, it can include pull-down load resistors R40 and R41. Otherwise, an SRAM cell 300 can operate in the same general fashion as the SRAM cell of FIG. 2, and be subject to the same variations in construction.

In this way, an SRAM cell can include a latch circuit having coupled JFET devices cross-coupled between complementary data storage nodes and including pull-up or pull-down load resistors, as well as a BJT access circuit connected one or more of the data storage nodes.

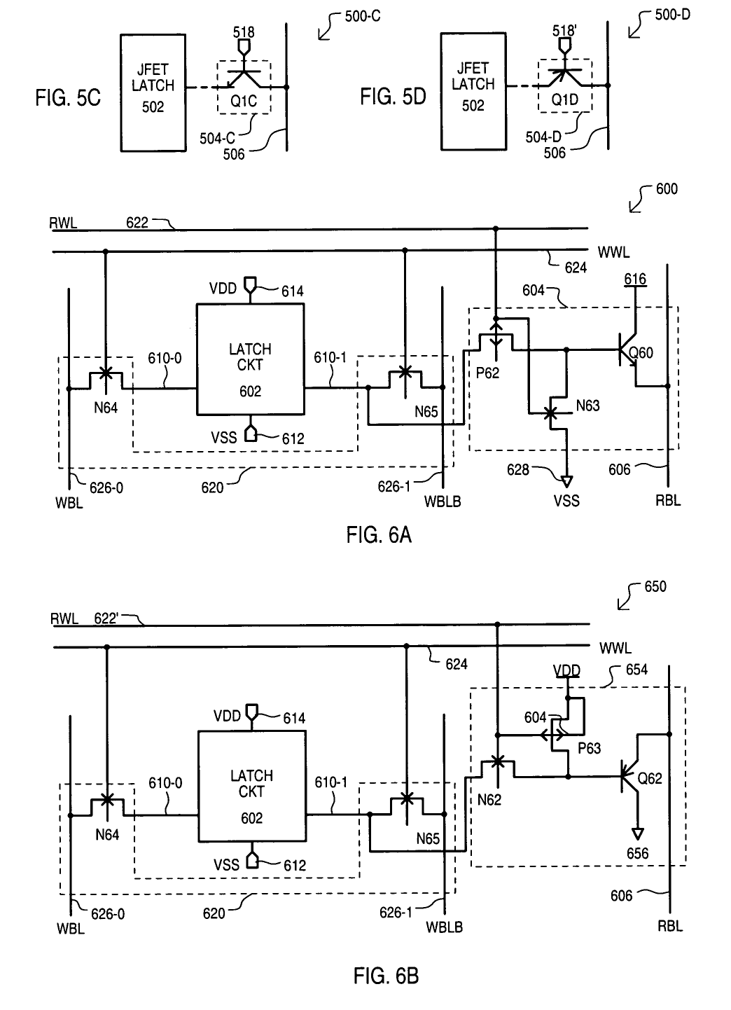

The above embodiments have described SRAM cells with JFET based latches connected to BJT based access circuits that are connected to bit lines. Various examples of possible access circuit arrangements will now be described with reference to FIGS. 5A to 5D.

FIGS. 5A to 5D show SRAM cells according to various embodiments, each such embodiment including a JFET latch 502 and an access circuit 504-(A-D). A JFET latch 502 can have a structure according to any of the JFET latches shown herein, or equivalents. Each access circuit 504(A-D) is shown to include a BJT device (Q1A-D). However, the manner by which each BJT device is connected between its corresponding latch circuit and bit line varies between embodiments.

In the arrangement of FIG. 5A, an access circuit 504A can include an npn BJT Q1A having a base connected to latch circuit 502 an emitter connected to a bit line 506, and a collector connected to a collector supply node 516. A collector supply node 516 can receive a voltage that remains constant as the SRAM cell 500-A stores data, writes data, and reads data. Alternatively, a voltage applied to collector supply node 516 can vary according to operation. A voltage applied at collector supply node 516 should be sufficient to maintain the base-collector pn junction in a reversed bias state during a read operation.

An arrangement like that of FIG. 5A can provide for advantageously fast responses when utilized with a preferred novel BJT device as described herein. A preferred novel BJT device can include an emitter having a substantially smaller capacitance than its corresponding collector. Thus, multiple BJTs can be connected to a bit line without increasing capacitance to large extent. This can allow data values to be driven on a bit line at a faster speed.

The arrangement of FIG. 5B shows the same essentially configuration as FIG. 5A, but with a pnp BJT Q1B. Consequently, BJT Q1B can have a collector connected to a collector supply node 516′ that can receive a different collector voltage for generating the reverse bias base-collector junction of BJT Q1B.

While an SRAM cell of the embodiments of FIGS. 5A and 5B includes access circuit BJTs having bases connected to a latch circuit and emitters connected to bit lines, alternate embodiments can have different BJT connections. Examples of two such embodiments are shown in FIGS. 5C and 5D.

In the arrangement of FIG. 5C, an access circuit 504-C can include an npn BJT Q1C having a collector-emitter path connected between latch circuit 502 and bit line 506. A base of BJT Q1C can be connected to a word line node 518. In such an arrangement, during a read operation, a word line node 518 can be driven to a potential sufficient to place the collector-emitter path of BJT Q1C into a low impedance state. While FIG. 5C shows BJT Q1C having an emitter connected to a latch circuit 502 and a collector connected to a bit line 506, an alternate arrangement can include the reverse (e.g., emitter connected to bit line 506 and collector connected to latch circuit 502). In such a reverse arrangement, a bit line 506 could be driven to a lower voltage in a read operation, to ensure proper biasing of BJT Q1C.

The arrangement of FIG. 5D shows the same essentially configuration as FIG. 5C, but with a pnp BJT Q1D. Consequently, biasing of BJT Q1D can be switched to ensure it can be placed into a low impedance state during a read operation.

In this way, SRAM devices can include access circuits with BJTs connected to JFET latch circuits in various ways.

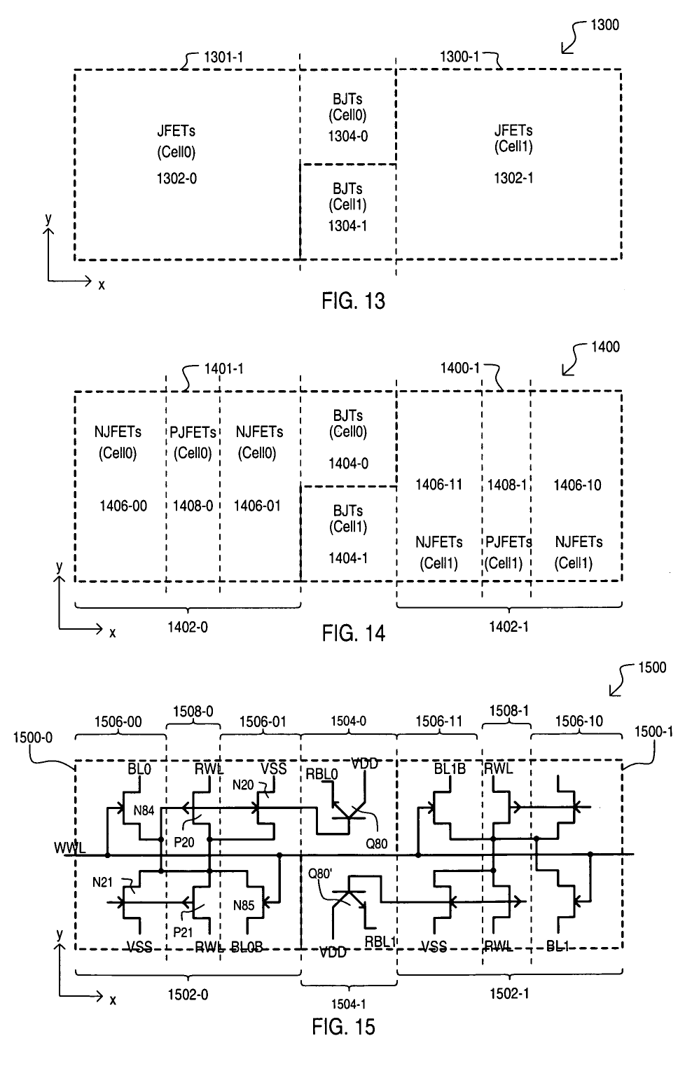

Referring now to FIGS. 6A and 6B, SRAM cells according to additional embodiments are shown. In very particular arrangements, the embodiment of FIG. 6A can be one example of an embodiment shown in any of FIGS. 1-4, 5A, or a portion of the embodiments shown in FIGS. 13-14 or 21. FIG. 6B can be one example of an embodiment shown in any of FIGS. 1-4, 5B, or a portion of the embodiments shown in FIGS. 13-14 or 21.

Referring to FIG. 6A, an SRAM cell 600 is shown in a block schematic diagram, and can include a latch circuit 602, an access circuit 604, a bit line 606, a write access circuit 620, a read word line (RWL) 622, a write word line (WWL) 624, and write bit lines 626-0/1. A latch circuit 602 can be connected between a first latch supply node 612 and a second latch supply node 614 and can provide a data value in complementary form at first and second data nodes 610-0 and 610-1. A latch circuit 602 can take the form of any of the JFET latch circuits shown herein, or equivalents, and preferably includes cross-coupled complementary JFETs, like the configuration shown in FIG. 2. In the particular arrangement of FIG. 6A, a first latch supply node 612 can receive a first power supply voltage VSS that does not change between write, store, and read operations. Similarly, a second latch supply node 614 can receive a second power supply voltage VDD that does not change between write, store, and read operations. Preferably, a power supply voltage range (e.g., VDD-VSS) can be less than that forward bias voltage of pn junctions formed within the JFETs of latch circuit 602, for example, can be about +0.5 V. This can provides a very low operating voltage desirable for low power applications, as less than a typical operating voltage of a MOSFET type transistor.

Referring still to FIG. 6A, an access circuit 604 can include an npn BJT Q60, a read JFET P62, and a disable JFET N63. BJT Q60 can have a collector connected to a collector supply node 616, a base connected to second data node 610-1 by read JFET P62, and an emitter connected to bit line 606. Read JFET P62 can provide a read data path between latch circuit 602 and BJT Q60, and can have a drain connected to second data node 610-1, a gate connected to read word line 622, and source connected to a base of BJT Q60. Read JFET P62 is a PJFET in the particular example shown. A disable JFET N63 can ensure BJT Q60 remains in a high impedance state when data is not being read to bit line 606. Disable JFET N63 has a drain connected to a base of BJT Q60, a gate connected to read word line 622, and a source connected to a low power supply node 628. Disable JFET N63 of FIG. 6 can be an NJFET.

A write access circuit 620 can provide a write data path to latch circuit 602 to enable data to be written into the latch circuit 620. In the example of FIG. 6, a write access circuit 620 can include a first write JFET N64 and a second write JFET N65. A first write JFET N64 can have a source-drain path connected between a first write bit line 626-0 and a first data node 610-0, and a gate connected to a write word line 624. A second write JFET N65 can have a source-drain path connected between a second write bit line 626-1 and a second data node 610-1, and a gate connected to a write word line 624.

JFETs N63 to N65 can include bodies (or second “back” gates). In one arrangement, such back gates can be connected to a low power supply node 628. In alternate embodiments, either such back gate can be driven in tandem with the corresponding (front) gate, or driven to a lower than supply voltage when turned off to provide a very low leakage state. In a similar fashion, JFET P62 can also include a body (or second “back” gate). Like JFETs N63 to N65, such a back gate can be connected to a power supply node (e.g., a high power supply node that receives VDD), or driven in tandem with the corresponding (front) gate, or driven to a higher than supply voltage (a voltage greater than VDD) when turned off.

While a write access circuit 620 is preferably a differential write that drives data nodes (610-0 and 610-1) to complementary voltage levels, alternate embodiments can include single ended arrangements. A single ended write access circuit could include a single write JFET (e.g., N64 or N65) connected to a write bit line (e.g., 626-0 or 626-1).

Having described the construction of SRAM cell 600 shown in FIG. 6, operations of the embodiment will now be described.

In an idle state, an SRAM cell 600 can retain a data value. In such an operation, a write word line 624 can be at a sufficiently low voltage (e.g., VSS) to place write JFETs N64 and N65 into a high impedance that prevents a data value stored in latch circuit 602 from being disturbed by variations on write bit lines 626-0 and 626-1. At the same time, a read word line 622 can be at a sufficiently high voltage (e.g., VDD) to place read JFET P62 into a high impedance state and disable JFET N63 into a low impedance state. Such an arrangement can prevent a data value stored at second data node 610-1 from propagating to a base of BJT Q60, and thus ensure that BJT Q60 remains turned off (does not provide substantial current to bit line 606).

In a write operation, a write access circuit 620 can be enabled, and a data value written into latch circuit 602. In such an operation, initially a write word line 624 can be low while a read word line 622 can be high, as in the store operation. However, a write amplifier (not shown) can drive write bit lines 626-0/1 to opposite logic states (e.g., one write bit line at VDD while the other write bit line is at VSS). A write word line 624 can then transition high, to place write JFETs N64 and N65 into a low impedance states, thus enabling a data value present on write bit lines 626-0/1 to be latched by latch circuit 602. Read word line 622 can remain high, continuing to disable BJT Q60 and isolate bit line 606 from latch circuit 602.

In a read operation, if latch circuit 602 stores one data value, a BJT Q60 can be enabled, allowing current to flow to bit line 606. However, if latch circuit 602 stores another value, a BJT Q60 can remain essentially disabled, and little or essentially no current can flow to bit line 606. In a read operation, initially a write word line 624 can be low while a read word line 622 can be high, as in the store operation. Subsequently, a read word line 622 can transition low (e.g., to VSS) placing read JFET P62 into a low impedance state. At the same time, disable JFET N63 can be placed into a high impedance state, allowing a base of BJT Q60 to be driven according to a potential at second data node 610-1. Prior to, or subsequent to, read word line 622 transitioning low, a read bit line 606 can be driven to a sufficiently low voltage to allow a base-emitter pn junction of BJT Q60 to be forward biased if a high voltage (e.g., VDD) at second data node 610-1 is applied to the base of BJT Q60 via read JFET P62. Further, a voltage at collector supply node 616 can be sufficiently high to reverse bias the base-collector pn junction of BJT Q60.

Thus, if second data node 610-1 is latched high (and first data node 610-0 latched low), BJT Q60 will be biased into an active region and will cause a substantial current flow from its collector to read bit line 606. If second data node is latched low (and first data node 610-0 latched high), then BJT Q60 will not be biased into the active region, and no substantial current will flow to read bit line 606.

Referring to FIG. 6B, another SRAM cell 650 is shown in a schematic diagram. SRAM cell 650 can have the same general construction as that of FIG. 6A, and be subject to the same variation. However, SRAM cell 650 can differ from that of FIG. 6A in that it can include an access circuit 654 having a pnp BJT Q62, a read JFET N62 that is an NJFET, and a disable JFET P63 that is a PJFET. In such a configuration, during a read operation, a read word line 622′ can start low and then transition high. Prior or subsequent to read word line 622 transitioning high, bit line 606 can be driven to a sufficiently high voltage to allow an emitter-base pn junction of BJT Q62 to be forward biased if a low voltage (e.g., VSS) stored at second data node 610-1 is applied to the base of BJT Q62 via read JFET N62. Further, a voltage at collector supply node 656 can be sufficiently low to reverse bias the collector-base pn junction if a stored low voltage is applied to the base of BJT Q60.

In this way, a data value can be stored, written to, and read from an SRAM cell having a JFET based latch circuit and BJT based access circuit.

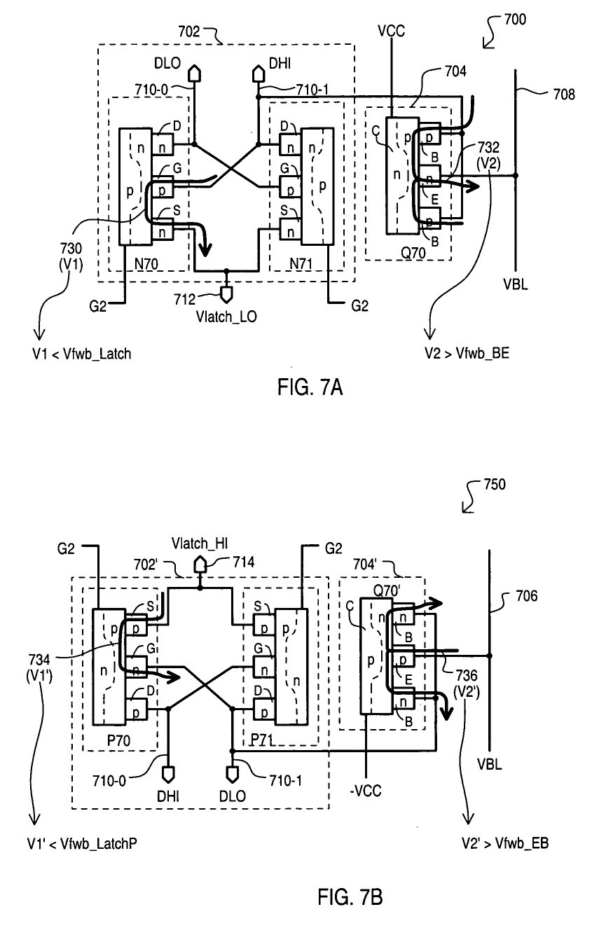

As noted above, preferably, a JFET based latch circuit operates at potentials below a forward bias voltage of pn junctions included within such JFET devices. However, at the same time, during a read operation, the application of a value stored in a latch should be sufficient to place a BJT device into an active region of operation. This biasing arrangement will be further described with reference to FIGS. 7A and 7B.

Referring now to FIG. 7A, an SRAM cell according to an embodiment is shown in a diagram and designated by the general reference character 700. In very particular arrangements, the embodiment of FIG. 7A can be one example of an embodiment shown in FIGS. 1 or 5A, or a portion of the embodiments shown in FIGS. 2, 3, 6A, 8A, 8C, 10A, 13-16 or 21.

An SRAM cell 700 can include a latch circuit 702 and an access circuit 704. A latch circuit 702 can include a first latch transistor N70 and a second latch transistor N71. Latch transistors (N70 and N71) are shown in diagram form that generally follows a side cross sectional view of the transistors, oriented vertically, and shows the conductivity type of semiconductor portions of such transistors. Thus, the particular case of FIG. 7A shows n-channel latch JFETs. Each of latch JFETs (N70 and N71) includes a drain (D), first gate (G), source (S), and second (back) gate (G2). Latch transistors (N70 and N71) are shown in a cross-coupled configuration between data nodes 710-0 and 710-1. Data nodes (710-0 and 710-1) can be connected to a passive or active load arrangement (not shown) to enable a latching of complementary values. Sources of latch transistors (N70 and N71) can be commonly connected to first latch supply node 712, which can be biased to a voltage Vlatch_LO.

In example of FIG. 7A, latch circuit 702 is assumed to latch a high voltage value (DHI) at a second data node 710-1 and a complementary low voltage value (DLO) at a first data node 710-0. It is understood that in such an arrangement, a voltage from second data node 710-1 to first latch supply node 712 can be positive, but not sufficient to forward bias the pn junction created by gate and source of latch transistor N70. This pn junction is shown by arrow 730 in FIG. 7A, and the voltage across the junction is identified as V1. As but one example, such a voltage difference can be less than +0.6 volts, preferably, about +0.5 volts. Again, such a range can be considerably smaller than an MOSFET based latch, which typically has to accommodate at least one type of threshold voltage (Vtn or Vtp), if not two threshold voltages (Vtn and Vtp).

Referring still to FIG. 7A, an access circuit 704 can include a BJT Q70. Like latch JFETs (N70 and N71), BJT Q70 is also shown in diagram form that generally follows a side cross sectional view of the transistor and shows the conductivity type of semiconductor portions within the transistor. BJT Q70 includes a collector (C), a base (B), and an emitter (E).

In example of FIG. 7A, it is assumed that a read operation is taking place, drawing current through BJT Q70 and supplying current to bit line 708. That is, the voltage at second data node 710-1 biases BJT Q70 into the active region. To achieve such a biasing arrangement, a voltage from second data node 710-1 to bit line 708 is positive, and large enough to forward bias the pn junction created by base and emitter of BJT Q70. This pn junction is shown by arrow 732 in FIG. 7A, and the voltage across the junction is identified as V2. At the same time, a base-collector pn junction remains reverse biased.

Thus, in a read operation according to the embodiment of FIG. 7A, the following conditions can apply:

V1<Vfwb_Latch and V2>Vfwb_BE

Where Vfwb_Latch is a minimum voltage required to forward bias the gate-source pn junction of a latch JFET (N70 or N71), and Vfwb_BE is a minimum voltage required to forward bias the base-emitter pn junction of a BJT Q70.

Referring now to FIG. 7B, an SRAM cell according to another embodiment is shown in a diagram and designated by the general reference character 750. In very particular arrangements, the embodiment of FIG. 7B can be one example of an embodiment shown in FIG. 1 or 5B, or a portion of the embodiments shown in FIG. 2, 4, 6B, 8B, 8C, 10B, 13-14, or 21.

Like FIG. 7A, the embodiment of FIG. 7B shows transistors in diagram form, so that doped regions of the devices are evident. FIG. 7B differs from that of FIG. 7A in that is shows a latch circuit 702′ that includes p-channel JFETs P70 and P71 with common sources connected to a second latch supply node 714. Further, an access circuit 704′ can include a pnp BJT Q70′. However, the same essential voltage constraints can exist.

For example, if it is assumed that latch circuit 702′ latches a low voltage value (DLO) at a second data node 710-1 and a complementary high voltage value (DHI) at a first data node 710-0, a voltage from a second latch supply node 714 to a second data node 710-1 (V1′) can be positive, but not sufficient to forward bias the pn junction created by gate and source of latch transistor P70. Further, assuming that a read operation is taking place, a voltage from bit line 708 to second data node 710-1 (V2′) is large enough to forward bias the pn junction created by base and emitter of BJT Q70′. This pn junction is shown by arrow 736 in FIG. 7B.

In this way, an SRAM cell latch formed by cross-coupled JFET devices can latch data values at voltage insufficient to forward bias pn junctions formed by such JFET devices. However, in a read operation from such an SRAM cell, the base-emitter pn junction of a BJT providing the read path can be forward biased.

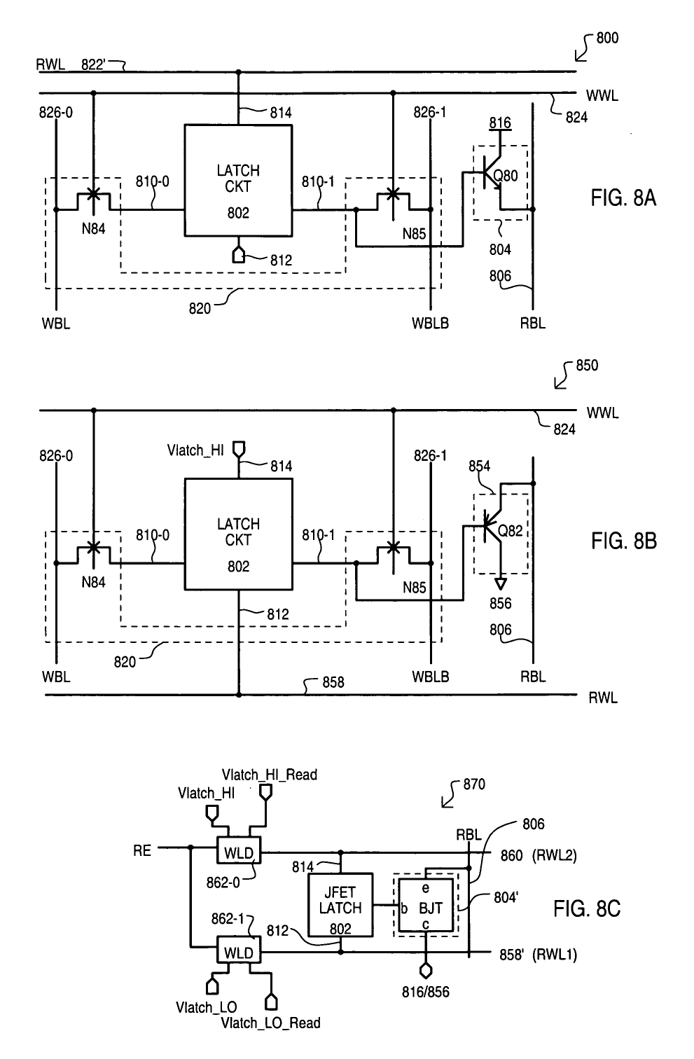

Referring now to FIGS. 8A to 8C, SRAM cells according to additional embodiments are shown in block schematic diagrams. In very particular arrangements, the embodiment of FIG. 8A can be one example of an embodiment shown in any of FIG. 1-4 or 5A, or a portion of the embodiment shown in FIG. 13-16 or 21.

Referring to FIG. 8A, an SRAM cell 800 can include a latch circuit 802, an access circuit 804, a bit line 806, a write access circuit 820, a read word line 822′, a write word line 824, and write bit lines 826-0/1. SRAM cell 800 can have some of the same features as SRAM cell 600 shown in FIG. 6A, and thus be subject to the same variations as FIG. 6A. SRAM cell 800 can differ from that of FIG. 6A in that a second latch supply node 814 does not receive a static voltage, but is dynamically driven and connected to a read word line 822′. In addition, an access circuit 804 includes only a BJT Q80 having a base directly connected to second data node 810-1.

Operations of the embodiment shown in FIG. 8A will now be described.

In a store operation, an SRAM cell 800 can store a data value as in the case of FIG. 6A. However, it is noted that read word line 822′ can drive second latch supply node 814 with a voltage sufficient to latch a data value (referred to herein as Vlatch_LO), but not forward bias pn junctions of JFETs within latch circuit 802.

Write operations can occur in the manner described for FIG. 6A, with write word line 824 being driven to a voltage sufficient to allow a data value on write bit lines 826-0/1 to force latch circuit 802 to latch the write data value.

As in the case of FIG. 6A, in a read operation of SRAM cell 800, if latch circuit 802 stores one data value, a BJT Q80 can be enabled, allowing current to flow to bit line 806, but if latch circuit 802 stores another value, a BJT Q60 can remain essentially disabled, and little or essentially no current can flow to read bit line 806.

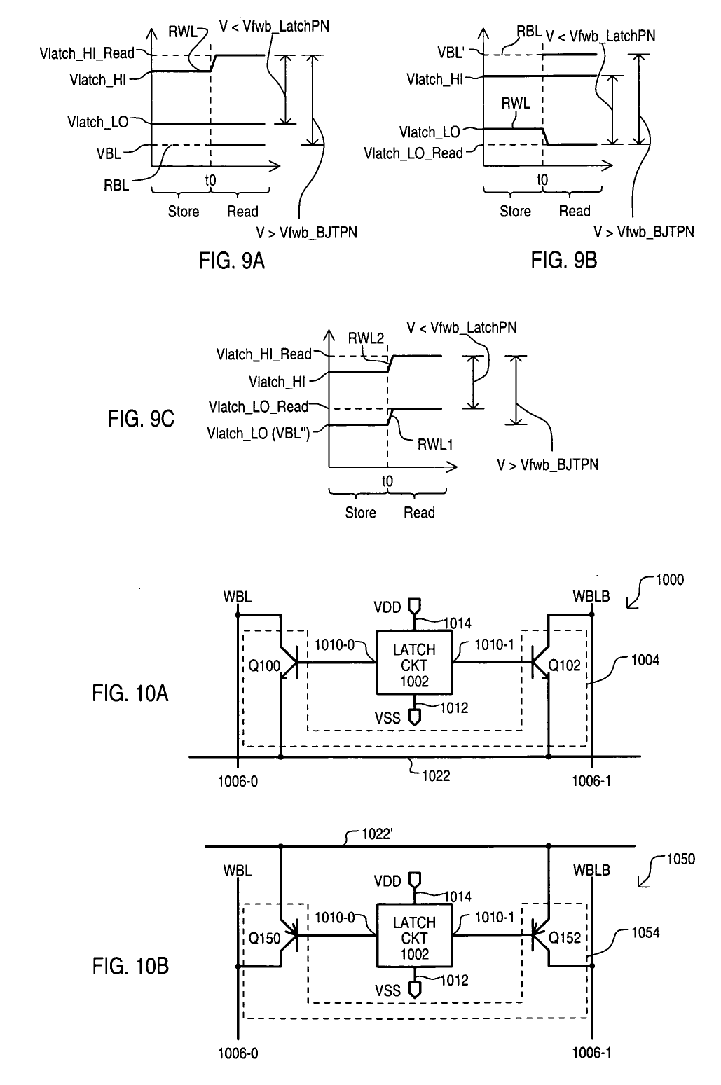

A read operation for the embodiment of FIG. 8A will now be described with reference to FIG. 8A in conjunction with FIG. 9A. Prior to time t0, a write word line 824 can be low level while a read word line (RWL) 822′ can be at a first high voltage (Vlatch_HI).

At about time t0, read word line (RWL) 822′ can transition to a voltage greater than Vlatch_HI, shown in FIG. 9A as Vlatch_HI_Read. Such an action can result in complementary data nodes latching one node at a static low level (Vlatch_LO) while the other data node is driven to the level Vlatch_HI_Read. It is understood that the difference between Vlatch_HI_Read and Vlatch_LO remains insufficient to forward bias pn junctions within latch circuit 802. That is, Vlatch_HI_Read-Vlatch_LO<Vfwb_LatchPN, where Vfwb_LatchPN is the voltage necessary to forward bias the JFET pn junctions. It is understood that the above read operation describes the selection of an SRAM cell 800. Such an operation can occur on a selected row of an array of such SRAM cells to enable the reading of data from all such cells in the row. At the same time data is being read from one row, other rows can be “de-selected”, by maintaining their read word lines at Vlatch_HI, which can prevent the base emitter junctions of BJT devices within such cells from being forward biased.

Prior to, or subsequent to time t0, read bit line (RBL) 806 can be at voltage VBL. The difference between voltage VBL and voltage Vlatch_HI_Read should be large enough to forward bias the base-emitter pn junction of BJT Q80. That is, Vlatch_HI_Read-VBL>Vfwb_BJTPN, where Vfwb_BJTPN is the voltage necessary to forward bias the base-emitter pn junction of BJT Q80. For de-selected cells, the voltage VBL is not sufficient to forward bias the base-emitter junction. That is, Vlatch_HI-VBL<Vfwb_BJTPN.

FIG. 8B shows another SRAM cell 850 in a block schematic diagram. In particular arrangements, SRAM cell 850 can be one example of an embodiment shown in any of FIGS. 1-4 and 5B, or a portion of the embodiments shown in FIG. 13-14, or 21. SRAM cell 850 can have some of the same features as SRAM cell 800, and can thus be subject to the same variation.

SRAM cell 850 can differ from that of FIG. 8A in that a first latch supply node 812 can be dynamically driven while a second latch supply node 814 can receive an essentially static voltage. In addition, an access circuit 854 can include a pnp BJT Q82.

Operations of the embodiment shown in FIG. 8B can be essentially the same as that of FIG. 8A for store and write operation.

Read operations for the embodiment of FIG. 8B will now be described in conjunction with FIG. 9B At about time t0, read word line (RWL) 858 can transition to a voltage lower than Vlatch_LO, in this case shown as Vlatch_LO_Read. This can result in data nodes 810-0 and 810-1 latching opposite states of Vlatch_HI and Vlatch_LO_Read. Like the case described for FIGS. 8A/9A, Vlatch_HI-Vlatch_LO_Read<Vfwb_LatchPN. For de-selected SRAM cells, the corresponding read word line can be maintained at Vlatch_LO.

Prior to, or subsequent to time t0, read bit line (RBL) 806 can be at voltage VBL′. The difference between voltage VBL′ and voltage Vlatch_LO_Read should be large enough to forward bias the base-emitter pn junction of BJT Q82. That is, VBL′-Vlatch_LO_Read>Vfwb_BJTPN. In the case of de-selected cells, base-emitter pn junctions of BJTs are not forward biased. That is, VBL′-Vlatch_LO<Vfwb_BJTPN.

While the embodiments of FIGS. 8A and 8B have shown arrangements in which one latch power supply node can be shifted to enable a read BJT device, it may be desirable to shift both latch power supply nodes in a same direction (i.e., both higher or both lower). Such an arrangement can maintain a low supply voltage across a latch circuit while at the same time providing margin for ensuring a sufficient voltage difference to enable a read BJT. An example of such an arrangement is shown in FIG. 8C.

Referring to FIG. 8C, an SRAM cell 870 can include a latch circuit 802, an access circuit 804′, and a bit line 806. A first read word line (RWL1) 858′ can be connected to a first latch supply node 812, and a second read word line (RWL2) 860 can be connected to a second latch supply node 814. In addition, SRAM cell 870 can include first word line driver 862-0 and a second word line driver 862-1. In response to a read signal RE, activated during a read operation, a first word line driver 862-0 can drive first read word line 858′ (and hence first latch supply node 812) from a level Vlatch_LO to Vlatch_LO_Read. Similarly, In response to a read signal RE, a second word line driver 862-0 can drive second read word line 860 (and hence second latch supply node 814) from a level Vlatch_HI to Vlatch_HI_Read. An SRAM circuit 870 can also include a write access circuit and one or more corresponding write bit lines. Such write access features are not shown to avoid unduly cluttering the view.

Read operations for the embodiment of FIG. 8C will now be described in conjunction with FIG. 9C

At about time t0, a first read word line (RWL1) 858′ can transition from voltage Vlatch_LO to a voltage Vlatch_LO_Read. In the example shown, Vlatch_LO_Read>Vlatch_LO. At the same time, a second read word line (RWL2) 858 can transition from voltage Vlatch_HI to a voltage Vlatch_HI_Read. In the example shown, Vlatch_HI_Read>Vlatch_HI. In such an arrangement, the difference between Vlatch_HI_Read and Vlatch_LO_Read can continue to be less than a latch JFET pn junction forward bias voltage (Vfwb_LatchPN). In the case of de-selected SRAM cells, a first read word line can remain at Vlatch_LO, and a second read word line can remain at Vlatch_HI.

Prior to, or subsequent to time t0, read bit line (RBL) 806 can be at voltage VBL″, which in this example can be the same as Vlatch_LO. Assuming an npn BJT is included in access circuit 804′, a difference between Vlatch_HI_Read and bit line voltage VBL″ can be greater than a forward bias voltage of the base-emitter pn junction of the BJT Vfwb_BJTPN. For de-selected cell, a difference between Vlatch_HI and the bit line voltage VBL″ is not greater than Vfwb_BJTPN.

It is understood that the SRAM cell of FIG. 8C could operate by driving latch supply nodes lower (i.e., Vlatch_LO_Read<Vlatch_LO and Vlatch_HI_Read<Vlatch_HI). In such a case, VBL″-Vlatch_LO_Read>Vfwb_BTJPN.

In this way, an SRAM cell can shift the potentials at which a JFET latch latches a data value in order to enable a BTJ read transistor. At the same time, a difference between such latched potentials can be less than that required to forward bias pn junctions of such JFETs.

Referring now to FIGS. 10A and 10B, SRAM cells according to further embodiments are shown in block schematic diagrams. In very particular arrangements, the embodiment of FIG. 6A can be one example of an embodiment shown in any of FIGS. 1-4, 5A, or a portion of the embodiments shown in FIG. 13-14 or 21. FIG. 6B can be one example of an embodiment shown in any of FIGS. 1-4, 5B, or a portion of the embodiments shown in FIG. 13-14 or 21.

Referring to FIG. 10A, an SRAM cell 1000 can include a latch circuit 1002, an access circuit 1004, bit lines 1006-0/1, and a word line 1022. A latch circuit 1002 can be connected between a first latch supply node 1012 and a second latch supply node 1014 and can provide a data value in complementary form at first and second data nodes 1010-0 and 1010-1. A latch circuit 1002 can take the form of any of the JFET latch circuits shown herein, or equivalents. In the particular arrangement of FIG. 10A, a first latch supply node 1012 can receive a first power supply voltage VSS that does not change between write, store, and read operations. Similarly, a second latch supply node 1014 can receive a second power supply voltage VDD that does not change between write, store, and read operations. Preferably, a power supply voltage range (e.g., VDD-VSS) can be less than that forward bias voltage of pn junctions formed within the JFETs of latch circuit 1002. As but one particular example, such a voltage range can be about +0.5 V.

Referring still to FIG. 10A, an access circuit 1004 can include a first npn BJT Q100 and a second npn BJT Q102. First BJT Q100 can have a collector connected to a first bit line 1006-0, a base connected to a first data node 1010-0, and an emitter connected to word line 1022. Second BJT Q102 can have a collector connected to a second bit line 1006-1, a base connected to a second data node 1010-1, and an emitter connected to word line 1022.

An SRAM cell 1000 can also include a write access circuit and one or more corresponding write bit lines. Such features are not shown to avoid unduly cluttering the view.

Having described the construction of SRAM cell 1000 shown in FIG. 10A, operations of the embodiment will now be described.

In a store operation, a word line 1022 can be at a sufficiently high voltage (e.g., VDD) to place BJTs (Q100 and Q102) into a high impedance state that can prevent a data value stored in latch circuit 1002 from being disturbed by variations on bit lines 1006-0/1. That is, base-emitter junctions of BJTs (Q100 and Q102) are not forward biased.

Write operations can occur according to any of the embodiments shown herein or equivalents.

In a read operation, if latch circuit 1002 stores one data value, a BJT Q100 can be enabled allowing current to flow to first bit line 1006-0, while BJT Q102 can be disabled, preventing current from flowing to second bit line 1006-1. However, if latch circuit 1002 stores another value, BJTs Q100 and Q102 can be in the opposite condition (BJT Q100 not conducting, and BJT Q102 conducting).

In a read operation, initially a word line 1022 can be high, as in the store operation. Subsequently, a word line 1022 can transition low, driving emitters of BJTs Q100 and Q102 low. Thus, if second data node 1010-1 is latched high (and first data node 1010-0 latched low), BJT Q102 will be biased into an active region, and will cause a bit line 1006-1 to discharge, while BJT Q100 can be in a non-conducting state, and essentially no current can flow from bit line 1006-0 to its collector. Conversely, if second data node 1010-1 is latched low (and first data node 1010-0 latched high), then BJT Q100 will not be biased into the active region, and no substantial current will flow from bit line 1006-0, while BJT Q101 can be in a conducting state, allowing current to flow from bit line 1006-0.

Referring to FIG. 10B, another SRAM cell 1050 is shown in a schematic diagram. SRAM cell 1050 can have the same general construction as that of FIG. 10A, and be subject to the same variation. SRAM cell 1050 differs from that of FIG. 10A in that it can include an access circuit 1054 having pnp BJTs Q150 and Q152. In such a configuration, during a read operation, a word line 1022′ can start low, ensuring that the base-emitter junctions of transistors Q150 and Q152 are not forward biased. To access data, word line 1022′ can then transition higher to allow either transistor Q150 or Q152 to be biased into the active region of operation depending upon whether first or second data node (1010-0 or 1010-1) is latched to a low level (e.g., VSS).

In this way, a data value can be read from an SRAM cell by driving an emitter of one or more BJT devices within such an SRAM cell, while bases of such BJT devices are driven by a stored data value.

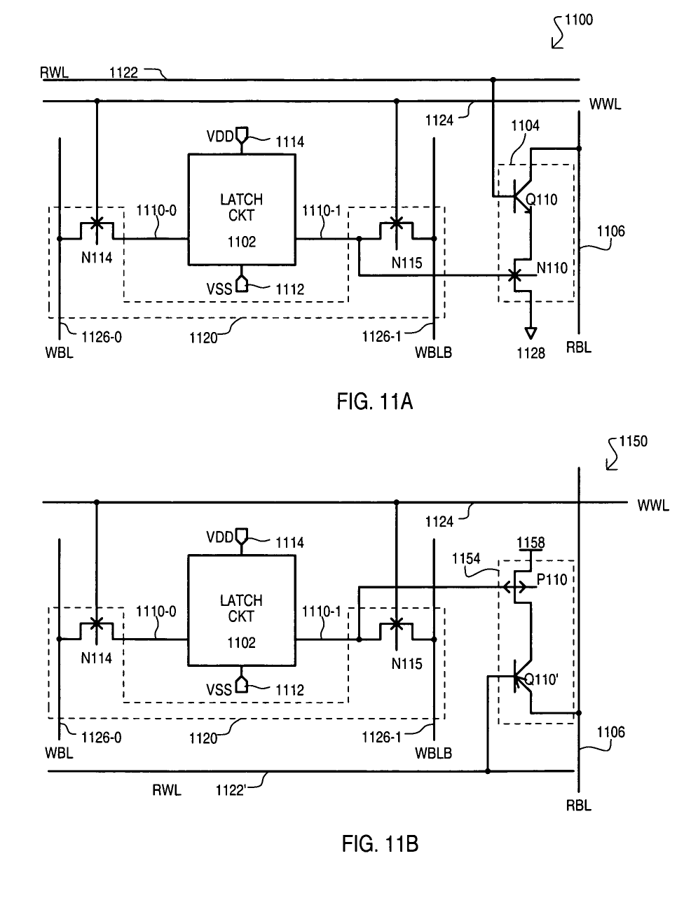

Referring now to FIGS. 11A and 11B, SRAM cells according to still more embodiments are shown in block schematic diagrams. In very particular arrangements, the embodiment of FIG. 11A can be one example of an embodiment shown in any of FIGS. 1-4 or a portion of the embodiments shown in FIG. 13-14, or 21.

Referring to FIG. 11A, an SRAM cell 1100 can include a latch circuit 1102, an access circuit 1104, a bit line 1106, a write access circuit 1120, a read word line 1122, a write word line 1124, and write bit lines 1126-0/1.

An SRAM cell 1100 can have some of the same features as SRAM cell 600 shown in FIG. 6A, thus, like structure can operate as described in FIG. 6A and be subject to the same variation as FIG. 6A. SRAM cell 1100 can differ from that of FIG. 6A in that an access circuit 1104 can have a different configuration. In particular, an access circuit 1104 can include an npn BJT Q110 and an enable JFET N110. BJT Q110 can have a collector connected to bit line 1106, a base connected to read word line 1122 and an emitter connected to a drain of enable JFET N110. Enable JFET N110 can have a gate connected to second data node 1110-1 and a source connected a low power supply node 1128.

Operations of the embodiment shown in FIG. 11A will now be described.

In a store operation, an SRAM cell 1100 can store a data value as in the case of FIG. 6A. That is, a first power supply voltage VSS at first latch supply node 1112 and a second power supply voltage VDD at a second latch supply node 1114, can be sufficient for latch circuit 1102 to latch a data value yet not forward bias pn junctions of JFETs within latch circuit 1102.

Write operations can occur in the manner described for FIG. 6A (and FIG. 8A).

In a read operation, initially a write word line 1124 can be low, placing write JFETs N114 and N115 into a high impedance state. At the same time, read word line 1122 can also be sufficiently low to ensure base-emitter junction of BJT Q110 is not forward biased. Subsequently, a read word line 1122 can transition high, forward biasing the base-emitter junction of BJT Q110. If a second data node 1110-1 is latched high (and first data node 1110-0 latched low), enable JFET N110 will provide a low impedance path for BJT N110 to a low power supply node 1128, resulting in current being drawn on bit line 1106. In contrast, if second data node 1110-1 is latched low (and first data node 1110-0 latched high), then enable JFET N1110 will have a high impedance, preventing BJT Q110 from drawing current from bit line 1106.

Referring to FIG. 11B, another SRAM cell 1150 is shown in a schematic diagram. SRAM cell 1150 can have the same general construction as that of FIG. 11A, and be subject to the same variation. However, SRAM cell 1150 can differ from that of FIG. 11A in that it can include an access circuit 1154 having an enable JFET P110 and a pnp BJT Q110′. In such a configuration, during a read operation, a read word line 1122′ can start high and then transition low, forwarding biasing the emitter-base junction of BJT Q110′. If second data node 1110-1 is latched low, current can flow into bit line, and if latched high, such a current will not flow into bit line 1106.

In this way, an SRAM cell can include an enable JFET that enables a current from a collector-emitter path of an access BJT to a power supply voltage based on a stored data value.

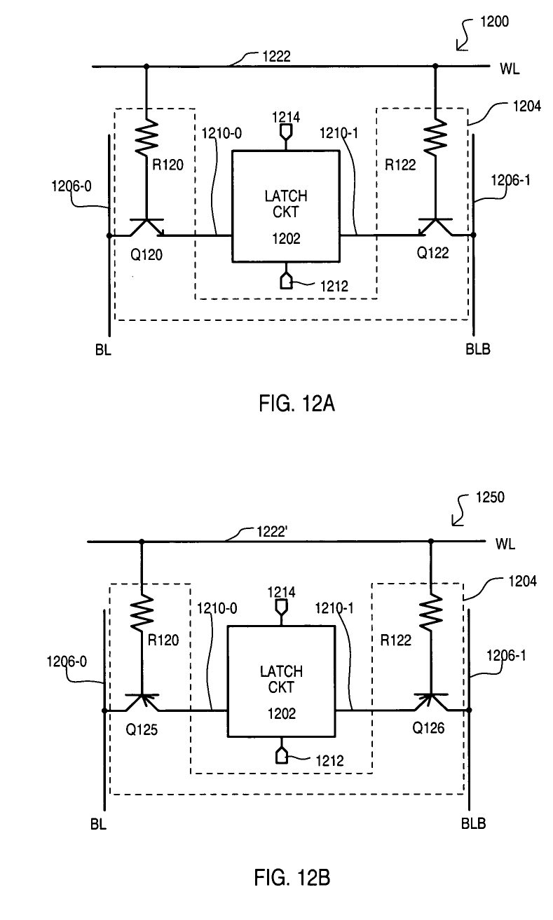

Referring now to FIGS. 12A and 12B, SRAM cells according to more embodiments are shown in block schematic diagrams. In very particular arrangements, the embodiment of FIG. 12A can be one example of embodiments shown in any of FIGS. 1-4, 5C, or a portion of the embodiments shown in FIG. 13-14, or 21.

Referring to FIG. 12A, an SRAM cell 1200 can include a latch circuit 1202, an access circuit 1204, and bit lines 1206-0/1.

An SRAM cell 1200 can have some of the same features as SRAM cell 600 shown in FIG. 6A, thus like structure can operate and described in FIG. 6A and be subject to the same variation as FIG. 6A. SRAM cell 1200 can differ from that of FIG. 6A in that an access circuit 1204 can have a different configuration, and serve as both a read access circuit and write access circuit. In particular, an access circuit 1204 can include a first npn BJT Q120 and a second npn BJT Q122, a first resistor R120, and second resistor R122. First npn BJT Q120 can have a collector connected to bit line 1206-0, a base connected to a word line 1222 by resistor R120, and an emitter connected to first data node 1210-0. In a similar fashion, second npn BJT Q122 can have a collector connected to bit line 1206-1, a base connected to word line 1222 by resistor R122, and an emitter connected to second data node 1210-1.

Operations of the embodiment shown in FIG. 12A will now be described.

In a store operation, an SRAM cell 1200 can store a data value as in the case of FIG. 6A. That is, a power supply voltages received at first and second latch supply nodes (1212 and 1214) latch data, yet do not forward bias pn junctions of JFETs within latch circuit 1202.

In a write operation, a word line 1222 can be initially be low enough, that even if a data node (e.g., 1210-0 or 1210-1) was latched low, a base-emitter junction of a corresponding BJT (e.g., Q120 or Q122) would not be forward biased. Further, bit lines 1206-0/1 can be driven to complementary values according to the data value to be stored. Subsequently, a word line 1222 can transition high enough to forward bias base-emitter junctions of the BJT (Q120 or Q122) connected to the data node (1210-0 or 1210-1) that is latched low. The turning on of a BJT (Q120 or Q122) can result in the data on bit lines 1206-0/1 being written into the latch circuit 1002, if the latch circuit does not already store the write value.

In a read operation, initially word line 1222 can be low, as in the case of the write operation. However, rather than be driven to complementary values, bit lines 1206-0/1 can be equalized to a same value. Subsequently, a word line 1222 can transition high enough to forward bias base-emitter junctions of the BJT (Q120 or Q122) connected to the data node (1210-0 or 1210-1) that is latched low. As a result, the corresponding bit line (1206-0 or 1206-1) can draw current, thus indicating the stored data value.

Referring to FIG. 12B, another SRAM cell 1250 is shown in a schematic diagram. SRAM cell 1250 can have the same general construction as that of FIG. 12A, and be subject to the same variation. However, SRAM cell 1250 can differ from that of FIG. 12A in that it can include an access circuit 1254 having pnp BJTs Q125 and Q126. In such a configuration, during a read operation, a read word line 1222′ can start high and then transition low, forwarding biasing the emitter-base junction of the BJT (Q125 or Q126) having an emitter connected to a data node latched to a low value.

In this way, an SRAM cell can include BJTs having emitter-collector current paths connected between bit lines and data nodes of a JFET latch circuit, as well as bases commonly connected to a word line.

Having described SRAM cells according to various circuit configurations, examples of SRAM cells layouts will now be described.

Referring to FIG. 13, a memory device SRAM layout is shown in a top plan view and designated by the general reference character 1300. An SRAM layout 1300 can include a first SRAM cell 1300-0 adjacent to as second SRAM cell 1300-1 in a first direction (shown as “x”). Each SRAM cell (1300-0 and 1300-1) can include a JFET section 1302-0 and 1302-1 and a BJT section 1304-0 and 1304-1. Each JFET section 1302-0/1 can include JFET devices for the corresponding SRAM cell, preferably cross-coupled latch JFETs as described above. In a preferred embodiment, such JFETs can include gate, source and drain terminals formed by a semiconductor layer formed on a surface of a substrate. Even more preferably, a gate region can be formed by such a gate terminal outdiffusing dopants into a substrate over a channel region.

Each BJT section 1304-0/1 can include one or more BJTs that can allow data be read from the corresponding SRAM cell 1300-0/1. As shown, BJT sections 1304-0/1 for different SRAM cells can be aligned with one another in a second direction (show as “y”) perpendicular to the first direction. Such an arrangement of BJTs in the second direction can allow for common connection of SRAM cells 1300-0/1 to a same bit lines (or bit line pair) to made in a relatively easy fashion.

In this way, SRAM cells can be formed adjacent to one another in a first direction with BJT formation sections that are aligned with one another in a second direction perpendicular to the first direction.

Referring now to FIG. 14, another memory device SRAM layout is shown in a top plan view and designated by the general reference character 1400. In one very particular arrangement, FIG. 14 can be one example of the layout shown in FIG. 13.

Like FIG. 13, FIG. 14 shows two SRAM cells 1400-0 and 1400-1 having JFET sections 1402-0/1 and BJT sections 1404-0/1. However, unlike FIG. 13, JFET sections 1402-0/1 show different regions for forming JFETs of different conductivity type. In particular, JFET section 1402-0 can include a first NJFET region 1406-00, a second NJFET region 1406-01, and a PJFET region 1408-0. Such FET regions (1406-00, 1406-01, 1408-0) can be contiguous in a same direction (shown as “y”). NJFETs can be formed NJFETs regions (1406-00 and 1406-01), which can include p-type substrate regions in which n-type channels can be formed. Similarly, PJFETs can be formed in PJFET region 1408-0, which can include an n-type substrate region in which p-type channels can be formed. In a like manner, JFET section 1402-1 can include a first NJFET region 1406-10, a second NJFET region 1406-11, and a PJFET region 1408-1.

In this way, SRAM cells can be formed adjacent to one another with JFET sections having regions for forming JFETs of different conductivity types, preferably contiguous in one direction.

Referring now to FIG. 15, another memory device SRAM layout is shown in a top plan view and designated by the general reference character 1500. In one very particular arrangement, FIG. 14 can be one example of the layout shown in FIG. 13 or 14.

Like FIGS. 13 and 14, FIG. 15 shows two SRAM cells 1500-0/1. Unlike the previous layout examples, FIG. 15 shows locations of particular circuit devices. More particularly, FIG. 15 shows one layout example for the circuit shown in FIG. 8A in which the latch circuit includes cross-coupled complementary JFETs as shown in FIG. 2. Thus, JFETs of FIG. 15 have the same labels as those shown in FIGS. 2 and 8A. NJFETs N84 and N21 can be formed in a contiguous NFET region 1506-00 that extends in the “y” direction. In the same manner, NJFETs N20 and N85 can be formed a contiguous NFET region 1506-01 also extending in the “y” direction, while PJFETs P20 and P21 are formed in PJFET region 1508-0 extending in the same “y” direction.

BJTs Q80 and Q80′ (of different SRAM cells) can be formed in BJT sections 1504-0/1 aligned in the “y” direction.

The arrangement of devices within SRAM cell 1500-1 is understood from the arrangement of SRAM cell 1500-0.

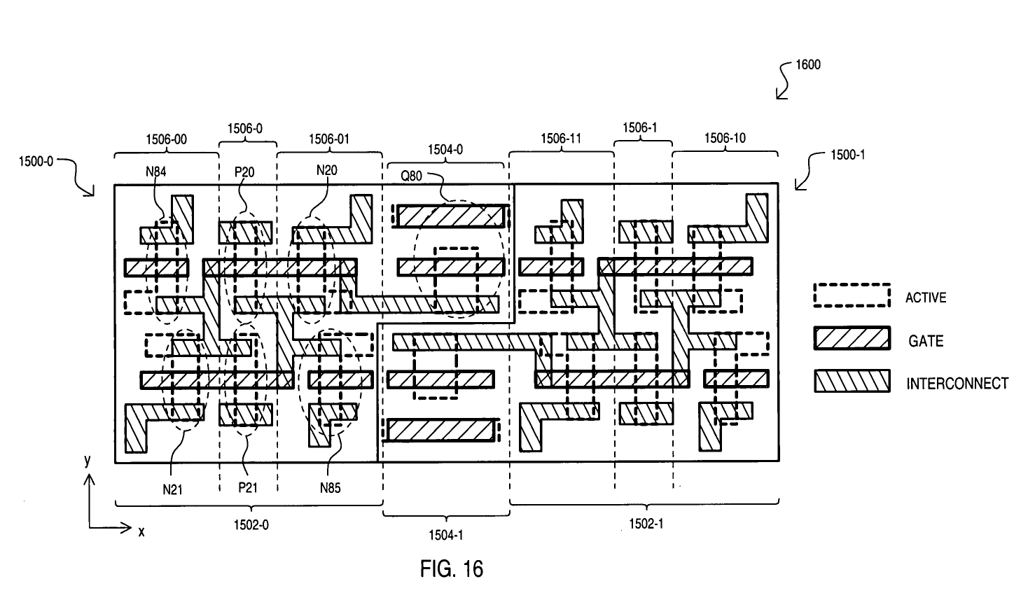

FIG. 16 shows one very particular example of the layout shown in FIG. 15, designated by the general reference character 1600.

FIG. 16 shows fabrication layers for forming the devices of SRAM cells 1600-0/1. As illustrated by the key, such layers include active region structures, electrode structures, and interconnect structures. Active region structures include substrate areas doped to appropriate conductivity type. Electrode structures are formed from patterning and doping a semiconductor layer, and are in direct contact with active region structures. Electrode structures can form gate electrodes, drain electrodes, and source electrodes for JFET devices, as well as base electrodes, emitter electrodes, and collector electrodes for BJT devices. Interconnect structures can provide conductive paths between electrodes of the BJT and JFET devices. In a preferred embodiments, electrode structures and interconnect structures are formed from a common layer of polycrystalline or amorphous silicon with a layer of silicide formed thereon.

In this way, an SRAM cell can include common types of devices (i.e., NFETs, PJFETs and BJTs) aligned with on another in a same direction, having electrodes and interconnections formed from a common deposited layer.

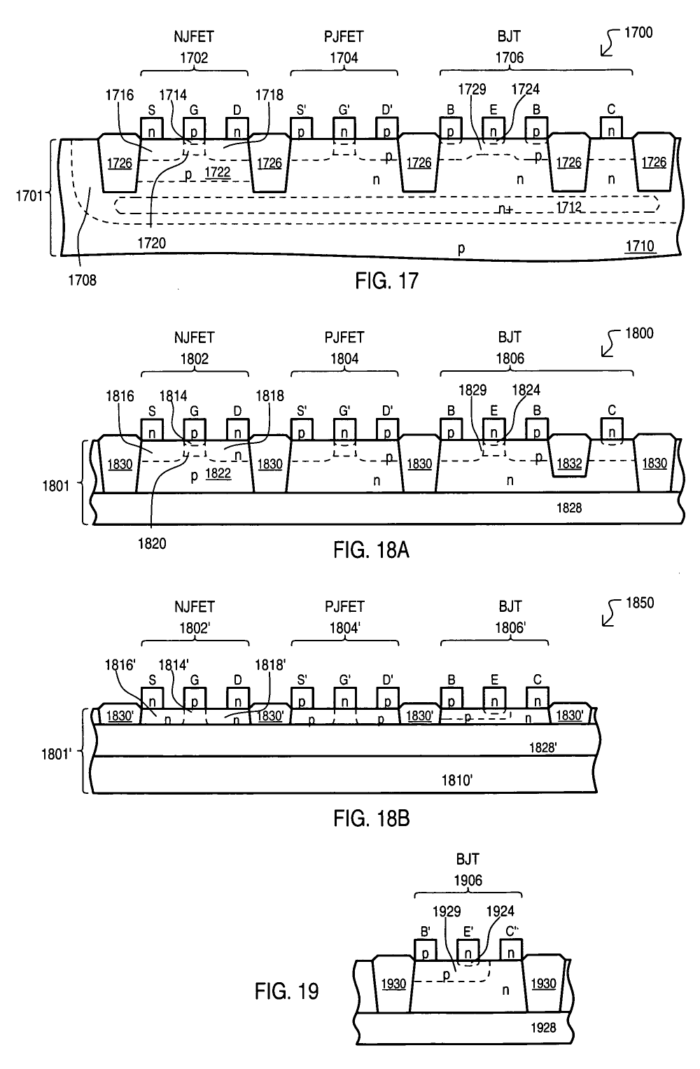

Referring now to FIG. 17, an example of device structures that can be included in the above embodiments is shown in a side cross sectional view of a device 1700. A device 1700 can be formed in a substrate 1701 and include an NJFET 1702, a PJFET 1704, and an npn BJT 1706. The devices (1702, 1704 and 1706) can be contained in a same an n-type well 1708 formed in a p-type substrate 1710. In the particular example shown, an n-well 1708 can further include an n+ layer 1712 below the devices (1702, 1704 and 1706). The n+ layer 1712 can provide a low resistance path for supplying a bias voltage to body regions of other JFET devices from the collector of BJT 1706. It is understood that any NJFETs, PJFETs or BJTs of the various embodiments can have a structure like that of NJFET 1072, PJFET 1704, or BJT 1706, respectively.

An NJFET 1702 can include a source electrode (S), gate electrode (G) and drain electrode (D) formed from a doped semiconductor material formed on, and in contact with a top surface of substrate 1701. Gate electrode (G) can be doped to a conductivity type (p) that is opposite to that of source/drain electrodes (S/D). Further, due to outdiffusion of dopants from a gate electrode, a p+ gate region 1714 can extend into a surface of substrate 1701 below gate electrode (G). Within a substrate 1701, NJFET can also include a highly doped n-type source region 1716 and drain region 1718 formed below and in physical contact with source electrode (S) and drain electrode (D), respectively. A more lightly doped n-type channel 1720 can extend between source/drain regions 1716/1718 below gate region 1714 and above a p-type back gate region 1722. It is noted that such an arrangement can form enhancement mode type JFET devices suitable for use in JFET based SRAM latches, described herein. It is understood that a back gate region 1722 can be contacted to back gate electrode (not shown) formed on a surface of substrate 1701.

A PJFET 1704 can have essentially the same structure as NJFET 1702, with oppositely doped elements. In addition, a back gate region for the PFET 1704 can be a portion of n-well 1708. Gate, source and drain electrodes for PJFET are shown as G′, S′ and D′, respectively.

A BJT 1706 can be advantageously formed with the same general process steps as NJFET 1702 and PJFET 1704. A BJT 1706 can include base electrodes (B), an emitter electrode (E), and a collector electrode (C) formed from a same semiconductor material as source/drain/gate electrodes for NJFET 1702 and PJFET 1704. Such electrodes can also be in contact with a top surface of substrate 1701. Further, due to outdiffusion of dopants from emitter electrode (E), an emitter region 1724 can extend into a surface of substrate 1701 below emitter electrode (E). A base region 1729 can be formed below base and emitter electrodes (B and E), and can include a p-type doped region. In such an arrangement, a collector for the BJT can be formed by a portion of n-well 1708.

It is noted that a pnp BJT could be formed using the same general structure as NFET 1702, with a p-type collector electrode making contact with a collector region corresponding to a p-type back gate region.

The various devices can be separated from one another by isolation structures 1726, which can be shallow trench isolation (STI), in one embodiment.

The above arrangement can allow all memory cell active devices to be formed in a common well. This can provide for advantageously compact array structures, as separate isolation, buried layer, etc. is not needed for BJT devices.

It is noted that an arrangement like that described in FIG. 17 may be particularly suitable for embodiments like those shown in FIGS. 5A, 5B, 6A, 6B, 7A, 7B, 8A, and 8B that have emitters connected to bit lines. As understood from FIG. 17, a BJT 1706 (or corresponding pnp BJT) presents an emitter with much lower parasitic capacitance (with respect to its corresponding bit line) than the collector of the BJT device, due to its relatively small area. Thus, connecting multiple SRAM cells to a same bit line using such an emitter connection can add relatively little parasitic junction capacitance.

Referring now to FIG. 18A, another example of device structures that can be used in the above embodiments is shown in a side cross sectional view of a device 1800. Device 1800 shows the same transistor type as FIG. 17, but implements such devices with a semiconductor-on-insulator substrate 1801, such as a silicon-on-insulator (SOI) type substrate. In such an arrangement, each device (NFET 1802, PJFET 1804 and BJT 1806) can be formed within its own semiconductor region, and electrically isolated (with respect to the substrate 1801) from all other devices by a bottom substrate insulating layer 1828, and lateral isolation structures 1830.

In such an arrangement, back gates of JFETs (i.e., back gate of PJFET 1804) and a collector of a BJT (i.e., collector of BJT 1806) are not portions of a substrate or substrate well that is shared with another device. Accordingly, back gate regions for NJFET 1802 and PJFET 1804 can be driven by corresponding back gate electrodes (not shown) formed on a surface of substrate 1801, just as a collector region can be driven by a collector electrode C for BJT 1806. It is noted that in such back gate driving arrangements, a device isolator, like that shown as 1832 for BJT can be included for each device.

Referring now to FIG. 18B, another example of device structures that can be used in the above embodiments is shown in a side cross sectional view of a device 1850. Device 1850 shows the same transistor type as FIG. 18A, but implements such devices on an SOI substrate in a “fully depleted” fashion. That is, depletion regions formed by gates (G, G′) extend vertically all the way to bottom substrate insulating layer 1828′. In the example shown, a BJT device 1806′ can have an alternate structure to that shown in FIG. 18A. This alternate structure is shown in more detail in FIG. 19.

Referring to FIG. 19, an alternate structure for a BJT device is shown in a side cross sectional view. In the arrangement of FIG. 19, a BJT device 1906 can include a base electrode (B′), an emitter electrode (E′), and a collector electrode (C′) formed from a same semiconductor material as that used to form source/drain/gate electrodes JFETs in a same substrate. Due to outdiffusion of dopants from emitter electrode (E′), an emitter region 1924 can extend into a surface of substrate 1901 below the emitter electrode (E′). A base region 1929 can be formed below the emitter electrode (E′) and one base electrode (B′), a collector region 1928 can be formed in substrate 1901 below base region 1929, and can have a potential set by collector electrode (C′).

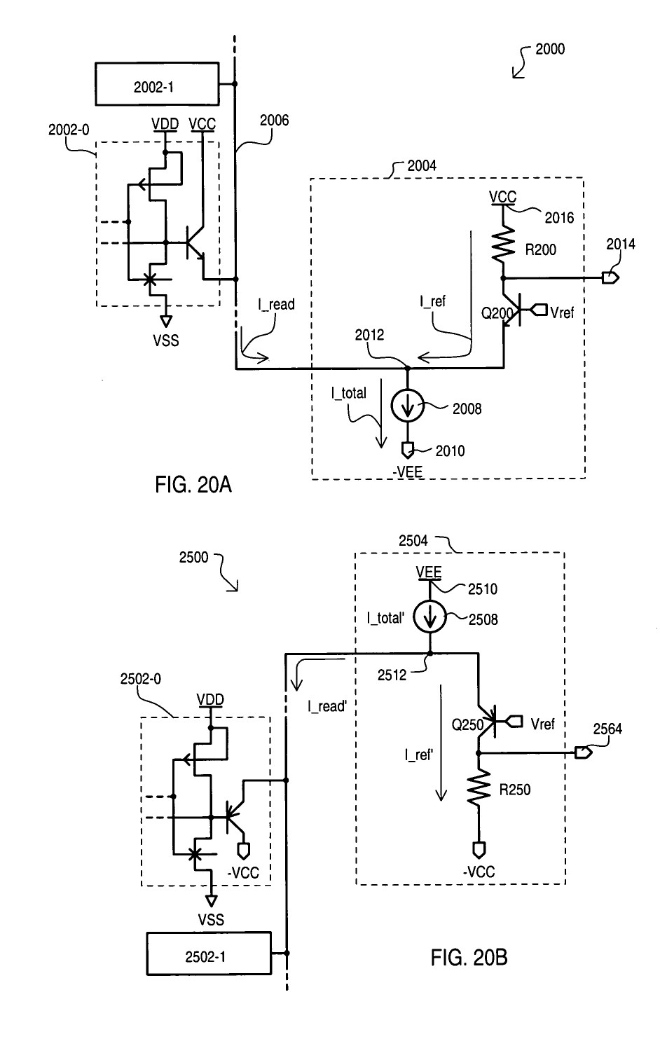

The above embodiments have shown arrangements in which an SRAM cell having JFETs and a read BJT can source or sink more current depending upon a data value stored. Such differences in current draw can sensed by a current sense amplifier to thereby determine a read data value for a cell. Two examples of possible current sense circuits are shown in FIGS. 20A and 20B.

FIG. 20A shows a current sensing arrangement in a block schematic diagram and designated by the general reference character 2000. Sensing arrangement 2000 shows SRAM cells 2002-0/1 and a current sense amplifier 2004 connected to a same bit line 2006. While a portion of SRAM cell 2002-0 is shown in schematic form, it is understood that SRAM cells 2002-0/1 can take the form of any of the JFET/BJT based SRAM cells shown in FIG. 1-4, 5A, 6A, 7A, 8A, 8C, or 13-16. When selected, an SRAM cell (2002-0 or 2002-1) can source an amount of current to bit line 2006 if one value is stored, or source a smaller amount of current (or essentially no current) if another value stored.

A current sense amplifier 2004 can include constant current source 2008, a reference BJT Q200, and a reference resistance R200. A constant current source 2008 can be connected between a sense power supply node 2010 and sink node 2012. Constant current source 2008 can draw a constant current I_total. Sink node 2012 can be formed at a common connection between bit line 2006 and an emitter of BJT Q200. BJT Q200 can include a base that receives a reference voltage Vref, and a collector connected to an output node 2014. Resistor R200 can be connected between output node 2014 and a high power supply node 2016.

The operation of the sense arrangement of FIG. 20A will now be described.

In a sense operation (e.g., a read operation of one of SRAM cells 2002-0/1), a selected SRAM cell can source a current I_read on bit line 2006. This current I_read will vary according to a data value stored by the selected SRAM cell. At the same time, current sense amplifier 2004 can be biased to draw a current Iref. Because constant current source 2008 sinks a constant current I_total, if current I_read has one value (e.g., is larger due to the stored data value), current I_ref will have a smaller value, and hence produce a relatively small voltage drop across resistor R200, resulting in a “high” voltage at output node 2014. In contrast, if current I_read has another value (e.g., is smaller, or essentially zero, due to the stored data value), current I_ref will have a larger value, and produce a relatively large voltage drop across resistor R200, resulting in a “low” voltage at output node 2014.

Referring now to FIG. 20B another sense arrangement 2500 is shown in a block schematic diagram. Sense arrangement 2500 follows the same general configuration as FIG. 20A, but is designed for sensing with pnp BJTs, instead of npn BJTs. Thus, SRAM cells 2502-0/1 can take the form of any of the JFET/BJT based SRAM cells shown in FIG. 1-4, 5B, 6B, 7B, 8B, 8C, or 13-14.

In a sense operation (e.g., a read operation of one of SRAM cells 2502-0/1), a constant current source 2508 can source a constant current I_total′ to bit line 2506 and current sense amplifier 2504. A selected SRAM cell can sink a current I_read′ that varies according to its stored data value. A current I_ref′ source by current sense amplifier 2504 will thus vary in a reciprocal fashion with respect to current I_read′, generating a voltage at output 2564 that varies according to the read data value.

In this way, a current that is sunk or sourced by an SRAM cell according to the embodiments can be sensed to determine the data value stored by the SRAM cell.

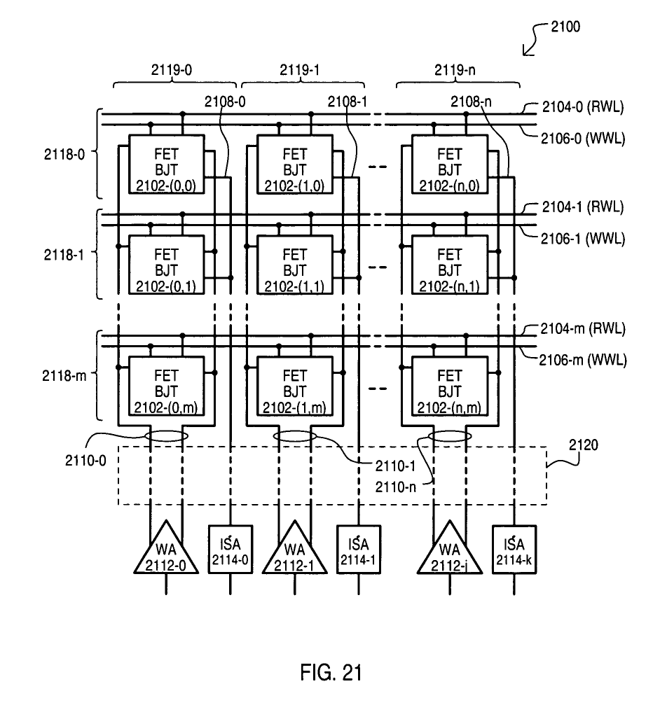

While the above description has shown SRAM cells according to various embodiments, embodiments of the invention can also include an SRAM device having an array of such SRAM cells. In such an array, SRAM cells can be arranged into rows and columns, with SRAM cells of a same row being commonly connected to one or more word lines, and SRAM cells of a same column being commonly connected to one or more bit lines. One particular example of such an arrangement in shown in FIG. 21.

Referring now to FIG. 21, one example of an SRAM device is shown in a block schematic diagram and designated by the general reference character 2100. An SRAM device 2100 can include SRAM cells 2102-(0,0) to 2102-(n,m), read word lines (RWL) 2104-0 to 2104-m, write word lines (WWL) 2106-0 to 2106-m, read bit lines 2108-0 to 2108-n, and write bit line pairs 2110-0 to 2110-n. FIG. 21 also includes write amplifiers 2112-0 to 2112-j, and current sense amplifiers 2114-0 to 2114-k. In the particular example of FIG. 21, SRAM cells (2102-(0,0) to 2102-(n,m)) are arranged in rows 2118-0 to 2110-m and columns 2119-0 to 2119-n.

In very particular arrangements, SRAM cells (2102-(0,0) to 2102-(n,m)) can take the form of any of the JFET/BJT SRAM cells shown in FIG. 1-8C, 11A-11B or 13-16.

In FIG. 21, SRAM cells of a same column are commonly connected to a corresponding read word line (2104-0 to 2104-m) and write word line (2106-0 to 2106-m). Thus, in a read operation, a row of SRAM cells can be selected to enable such SRAM cells to each provide read data on a corresponding read bit line (2108-0 to 2108-n). Similarly, in a write operation, a row of SRAM cells can be selected to receive write data driven on write bit line pairs (2110-0 to 2110-n).

Write amplifiers (2112-0 to 2112-j) can each drive a corresponding write bit line pair (2110-0 to 2110-n) to complementary values based on received write data. There can be a one-to-one correspondence between write amplifiers (2112-0 to 2112-j) and write bit line pairs (2110-0 to 2110-n) (i.e., j=n), or optionally, a column decoding circuit 2120 can be situated between write amplifiers (2112-0 to 2112-j) and write bit line pairs (2110-0 to 2110-n) (i.e., j<n), allowing one write amplifier to be multiplexed among multiple write bit line pairs.

Current sense amplifiers (2114-0 to 2114-k) can each sense a current sourced or sunk on a read bit line resulting from the selection of an SRAM cell. As in the case of the write amplifiers, there can be a one-to-one correspondence between current sense amplifiers (2114-0 to 2114-k) and read bit lines (2108-0 to 2108-n) (i.e., k=n), or optionally, a column decoding circuit 2120 can be situated between current sense amplifiers (2114-0 to 2114-k) and read bit lines (2108-0 to 2108-n) (i.e., k<n), allowing one current sense amplifier to be multiplexed among multiple read bit lines.

In very particular arrangements, current sense amplifiers (2114-0 to 2114-k) can each take the form of a current sense amplifier like that shown in FIG. 20A or 20B.

In this way, SRAM cells having JFET data storage portions and BJT read access portions can form an array accessible by current sense amplifiers and capable of receiving write data from write amplifiers.

Reference in the description to “one embodiment” or “an embodiment” means that a particular feature, structure, or characteristic described in connection with the embodiment is included in at least one embodiment of the invention. The appearance of the phrase “in one embodiment” in various places in the specification do not necessarily all refer to the same embodiment. The term “to couple” or “electrically connect” as used herein may include both to directly and to indirectly connect through one or more intervening components.

Further it is understood that the embodiments of the invention may be practiced in the absence of an element or step not specifically disclosed. That is, an inventive feature of the invention may include an elimination of an element.

While various particular embodiments set forth herein have been described in detail, the present invention could be subject to various changes, substitutions, and alterations without departing from the spirit and scope of the invention.

What is claimed is:

1. A static random access memory (SRAM) device, comprising:
at least one SRAM cell having
a storage section that includes at least a first junction field effect transistor (JFET) having a gate terminal formed from a semiconductor layer deposited on a substrate surface and at least a first storage node that provides a potential corresponding to a stored data value, and
a first access section that includes at least a first bipolar junction transistor (BJT) having an emitter formed from the semiconductor layer.

2. The SRAM device of claim 1, wherein:
the storage section comprises a latch circuit that includes the first JFET and a second JFET, the first JFET has a source coupled to a first latch supply node, a drain coupled to the first storage node and a gate connected to a second storage node, the second JFET has a source coupled to the first latch supply node, a drain coupled to the second storage node, and a gate coupled to the first storage node, and
the at least first BJT includes at least three BJT terminals, at least one of the three BJT terminals being coupled to the first storage node.

3. The SRAM device of claim 2, wherein:
the latch circuit further includes a third JFET and a fourth JFET of a different conductivity type than the first JFET and second JFET, the third JFET having a source coupled to a second latch supply node, a drain coupled to the first storage node and a gate connected to the second storage node, the fourth JFET having a source coupled to the second latch supply node, a drain coupled to the second storage node, and a gate coupled to the first storage node.

4. The SRAM device of claim 1, wherein:
the at least first BJT further includes a base and a collector, the base being coupled to the first storage node, the emitter being coupled to a first bit line, and the collector being coupled to an access power supply node.

5. The SRAM device of claim 4, wherein:
the first access section further includes at least a first access JFET having a source-drain path coupled between the first storage node and the base of the at least first BJT, and a gate coupled to a word line.

6. The SRAM device of claim 5, wherein:
the first access section further includes a disable JFET having a source-drain path coupled between the base of the at least first BJT and a disable power supply node, and a gate coupled to the word line.

7. The SRAM device of claim 1, wherein:
the at least one SRAM cell further includes
a second access section that provides a write data path to the storage section, the second access section including at least a first write access JFET having a source-drain path coupled between a first write bit line and the storage section, and a gate coupled to a write word line, and
the first access section provides a read data path from the storage section.

8. The SRAM device of claim 7, wherein:
the second access section further includes a second write access JFET having a source-drain path coupled between a second write bit line and the storage section, and a gate coupled to the write word line.

9. The SRAM device of claim 7, wherein:
the first write access JFET has a first source/drain terminal coupled to the at least one storage node and a second drain/source terminal coupled to the first write bit line; and
the at least first BJT has a base coupled to the at least one storage node and the emitter coupled to a read bit line.

10. The SRAM device of claim 1, wherein:
the at least first BJT further includes a base and a collector, the base being coupled to the at least one storage node, the collector being coupled to a first bit line, and the emitter being coupled to receive an access voltage that transitions from one potential to another to enable or disable access to the storage circuit.

11. The SRAM device of claim 10, wherein:
the at least first BJT and at least first JFET are formed in a semiconductor on insulator substrate, the at least first BJT includes a collector region of a first conductivity type formed in a first semiconductor substrate region surrounded by insulating material on one all but a top surface, a base region of a second conductivity type formed in the collector region, and the emitter electrode is in contact with the top surface of the first semiconductor region.

12. The SRAM device of claim 11, wherein:
the at least first JFET further includes an active region formed in a second semiconductor substrate region surrounded by insulating material on one all but a top surface, a source electrode and drain electrode are formed from the semiconductor layer, and the source, drain and gate electrodes are in contact with the top surface of the second semiconductor region.

13. The SRAM device of claim 1, wherein:
the at least first BJT further includes a base and a collector, the base being coupled to a word line that is commonly connected to a plurality of other SRAM cells, the emitter being coupled to the at least one storage node, and the collector coupled to a bit line.

14. The SRAM device of claim 1, wherein:
at least one SRAM cell includes a plurality of SRAM cells, each SRAM cell including a storage section having a plurality of JFETs configured into a latch and a first access section having a first bipolar junction transistor (BJT); and
a plurality of bit lines, each bit line being commonly coupled to the first BJT of a plurality of SRAM cells.

15. The SRAM device of claim 14, wherein:
each SRAM cell storage section comprises a latch circuit that includes the first JFET and a second JFET, the first JFET having a source coupled to a first latch supply node, a drain coupled to the first storage node and a gate connected to a second storage node, the second JFET has a source coupled to the first latch supply node, a drain coupled to the second storage node, and a gate coupled to the first storage node;
a plurality of word lines, each word line being commonly coupled to the first latch supply node of a plurality of SRAM cells; and
a word line driver corresponding to each word line, each word line driver driving its corresponding word line to a first potential when storing data values and a second potential when reading stored data values.

16. A method of storing and accessing a data value in an integrated circuit, comprising:
storing the data value in complementary form at a first data node and second node of a latch comprising at least a first junction field effect transistor (JFET) and second JFET, each JFET having p-n junctions formed between their respective gates and sources, and having sources commonly connected to a first latch power supply node, wherein a potential difference between the first latch power supply node and the first and second data nodes does not exceed a forward bias voltage of the p-n junctions when storing the data value; and
accessing the stored data value by selectively enabling a current path through a bipolar junction transistor (BJT) to a corresponding bit line based on the potential of at least the first data node.

17. The method of claim 16, wherein:
the latch further comprises a third JFET and fourth JFET of having p-n junctions formed between their respective gates and sources, and having sources commonly connected to a second latch power supply node, wherein a potential difference between the second latch power supply node and the first and second data nodes does not exceed a forward bias voltage of the third and fourth JFET p-n junctions when storing the data value.

18. The method of claim 16, wherein:
selectively enabling the current path through the BJT includes coupling the first data node to a base of the BJT through the source-drain path of an access JFET, the access JFET having a gate coupled to read word line commonly connected to a plurality of SRAM cells.

19. The method of claim 18, wherein:
selectively enabling the current path through the BJT includes selectively enabling a current path through an enable JFET having a source-drain path in series with an emitter-collector path of the BJT.

20. The method of claim 16, wherein:
the latch is coupled between the first latch power supply node and a second latch power supply node;
storing the data value further includes applying a first voltage to the first latch power supply node and a second voltage to the second latch power supply node; and
accessing the stored data value further includes applying a third voltage to the second power supply node where the difference between the third voltage and the first voltage is greater than the difference between the second voltage and the first voltage.

21. The method of claim 16, wherein:
the latch is coupled between the first latch power supply node and a second latch power supply node;
storing the data value further includes applying a first voltage to the first latch power supply node and a second voltage to the second latch power supply node; and
accessing the stored data value further includes applying a third voltage to the second power supply node that is different than the second voltage and applying a fourth voltage to the first power supply node that is different than the first voltage.

22. An static random access memory (SRAM) device, comprising:
a plurality of SRAM cells, each comprising at least two junction field effect transistors (JFETs) and at least one bipolar junction transistor (BJT) formed in a common substrate, the SRAM cells being commonly coupled to at least a first word line, each JFET including a gate terminal and at least one drain terminal both patterned from a same semiconductor layer formed on a surface of the common substrate, and the at least one BJT includes at least an emitter terminal formed on the surface from the semiconductor layer.

23. The SRAM device of claim 22, wherein:
the common substrate includes a semiconductor well region of a first conductivity type formed in bulk region of a second conductivity type, the JFETs and the at least one BJT being formed in the well region.

24. The SRAM device of claim 22, wherein:
the common substrate comprises a semiconductor-on-insulator substrate having isolated semiconductor regions isolated on a bottom surface by an insulating layer and on side surfaces by active area isolation structures formed with an insulating material, the JFETs and the at least one BJT each being formed in a different isolated semiconductor region.

25. The SRAM device of claim 22, wherein:
within each SRAM cell the at least two JFETs are a cross coupled pair that includes a first JFET having its gate conductively connected to the drain terminal of a second JFET, the gate terminal of the second JFET being conductively connected to the drain terminal of the first JFET, and
the at least one BJT includes base terminal formed on the surface of the common substrate from a semiconductor material doped to a different conductivity type than that of the emitter terminal, the base terminal being coupled to the drain terminal of the first JFET and the gate terminal of the second JFET.
